(19) United States
(12) Patent Application Publication
(10) Pub. No.: US 2022/0349541 A1
(43) Pub. Date: Nov. 3, 2022

(54) DEVICE AND METHOD FOR LIGHT EXPOSURE REGULATION OF AGRICULTURAL GOODS AND ENERGY PRODUCTION

(71) Applicant: Insolight SA, Lausanne (CH)

(72) Inventors: Florian Gerlich, Lausanne (CH); Laurent Coulot, Lausanne (CH); Mathieu Ackermann, Lausanne (CH); Noé Bory, Lausanne (CH); Gaël Nardin, Lonay (CH); David Schuppisser, Lausanne (CH)

(21) Appl. No.: 17/762,111

(22) PCT Filed: Sep. 24, 2020
(86) PCT No.: PCT/EP2020/076714

§ 371 Date: Mar. 21, 2022

(30) Foreign Application Priority Data
Sep. 24, 2019 (EP) 19199225.4

(51) Int. Cl. F21S 11/00; F21V 5/00; G02B 3/00; H01L 31/048; H01L 31/054

(52) U.S. Cl. CPC F21S 11/007; F21V 5/007; G02B 3/0068; H01L 31/048; H01L 31/0543; H02S 20/32

(57) ABSTRACT

The present invention relates to a device (100) for light exposure regulation of agricultural goods and energy production, in particular electrical energy production, by converting or transmitting a highly-directional component (81) of incident light (80) and by transmitting a diffuse component (82) of incident light (80), comprising: #an optical arrangement (40) comprising a first optical layer (41), wherein the first optical layer (41) comprises a plurality of primary optical elements (47); #a light energy conversion layer (50) at least partially transparent to light and comprising a plurality of distant light energy conversion elements (51) capable of converting light energy in an output energy; #a shifting mechanism (60) for moving the optical arrangement (40) relative to the light energy conversion layer (50) or vice versa; and #a frame element (10) to which either the optical arrangement (40) or the light energy conversion layer (50) is attached, wherein the shifting mechanism (60) is arranged to displace the optical arrangement (40) or the light energy conversion layer (50) translationally relative to the frame element (10), through one or more translation element (65), wherein the primary optical elements (47) of the first optical layer (41) and the shifting mechanism (60) are designed such that the highly-directional component (81) of incident light (80) is directable onto the light energy conversion elements (51) of the light energy conversion layer (50) and such that the diffuse component (82) of incident light (80) is transmittable through the regions of the light energy conversion layer (50) not covered by the light energy conversion elements (51), and wherein the amount of light transmitted through the device (100) is controllable. Furthermore, the present invention also relates to a corresponding method and use for converting light energy with the aforementioned device.

### TECHNICAL FIELD OF THE INVENTION

The present invention relates to the technical field of agricultural devices, in particular to the field of agricultural devices for illuminating agricultural goods. More specifically, the present invention relates to a device allowing to regulate the light exposure of agricultural goods to favour the growth of the latter while collecting the light not transmitted to the goods in order to produce energy. The present invention relates, furthermore, to the use of an inventive device in the field of agriculture as well as method for light exposure regulation of agricultural goods.

### BACKGROUND OF THE INVENTION

Illumination is one of the essential elements for the health and growth of agricultural goods, such as plants or crops. The intensity of the light and its quality will influence the elongation and magnification of the young growing cells in the stems, leaves and flowers. There is not an ideal light intensity quantity for all the plants, but this ideal luminosity depends on each type of agricultural goods. If the light intensity is not adequate, photosynthesis and growth will diminish and pale and smaller leaves, discoloured, brown or dry spots, etiolated plant with weak stems with greater distances between nodes, insect infestation, etc, will be observed. It is therefore primordial to favour the growth of agricultural goods to match the light exposure of the goods to the optimized exposure for each kind of goods. Is has been shown that by regulating the light exposure of agricultural goods, their growth can be positively influenced.

It is known in the technical field of agriculture to use devices with shutters, flaps or panes to regulate the light exposure of goods placed below these devices. However, these devices permit only to diminish the amount of light arriving at the goods. Furthermore, the light not transmitted to the goods is converted into heat and lost. Lastly, the light transmitted to the crops is typically not homogeneously distributed on the ground, producing alternance of sunlit and shaded areas.

It is also known in the art to install conventional silicon photovoltaics (PV) modules above crops or greenhouses. Conventional PV modules are very cheap and can be produced in mass. They are, however, completely opaque and therefore shade the plants placed below them completely if they are not sufficiently spaced apart. Spacing them apart, on the other hand, is not very effective, as it results in a decrease of the electricity production without completely removing shadows and without being able to regulate the light exposure of the agricultural goods. Furthermore, due to the sun movement throughout the course of the day plants can be completely deprived from sunlight.

Concentrated photovoltaics (CPV) is another solution with several advantages over conventional silicon PV. First, CPV modules can reach light conversion efficiencies well over 30%, whereas high-end silicon PV barely exceeds 20%. If the CPV modules comprise a transparent substrate, it can be semi-transparent or translucent. Therefore, sunlight scattered by the sky, diffused by the clouds or reflected by the environment can be transmitted through the CPV module to the ground with almost no shadowing. Finally, since the CPV modules require a tracking system to keep the solar cells in focus of the optics when the sun is moving, they can actively adjust the amount of direct sunlight converted to electricity by the cells, and the amount of sunlight which gets through unimpeded.

However, classical CPV module requires trackers that bear an important drawback. They are very heavy and complex structures, which require a large volume of free space to rotate around two axes, in order to follow the course of the sun in the sky. If they are mounted on the ground, they are likely to impede the movements of agricultural machines. Due to their size and weight, they are not compatible with rooftop installations and especially too heavy for greenhouse structures.

Finally, photovoltaic plants and agriculture are competing for land usage. Due to their relatively low energy conversion yield, both processes require very large open spaces with similar features such as decent amount of solar irradiance, relatively flat ground with minimal shading or obstacles, reasonable proximity with urban areas to alternatively produce electricity or grow food. Therefore, there is a strong incentive for an invention allowing both usages to share the same land.

For all the above reasons, there is a need for a device for light exposure regulation of agricultural goods and energy production, in particular electrical energy production. The device comprises a shifting mechanism that moves only within a limited volume, in order to track the apparent movements of the sun. With this device the light exposure of agricultural goods can be precisely controlled in order to favour the growth of the goods while using the light not transmitted to the goods for energy production.

### SUMMARY OF THE INVENTION

Thus, the object of the present invention is to propose a new device, corresponding method and uses for light exposure regulation of agricultural goods and energy production, in which the above-described drawbacks of the known systems and methods are completely overcome or at least greatly diminished.

An object of the present invention is in particular to propose a device and a corresponding method for light exposure regulation and energy production thanks to which it is possible to precisely control the amount of light transmitted through the device while converting the light energy not transmitted for energy production.

According to the present invention, these objects are achieved in particular through the elements of the four independent claims. Further advantageous embodiments arise from the dependent claims and the description. Features disclosed herein in different embodiments can also be combined easily by a person who is skilled in the art.

In particular, in a first aspect, the objects of the present invention are achieved by a device for light exposure regulation of agricultural goods and energy production, in particular electrical energy production, by converting or transmitting a highly-directional component of incident light and for transmitting a diffuse component of incident light, comprising
an optical arrangement comprising a first optical layer, wherein the first optical layer comprises a plurality of primary optical elements;
a light energy conversion layer at least partially transparent to light and comprising a plurality of distant light energy conversion elements capable of converting light energy in an output energy;
a shifting mechanism for moving the optical arrangement relative to the light energy conversion layer or vice versa; and
a frame element to which either the optical arrangement or the light energy conversion layer is attached,

wherein the shifting mechanism is arranged to displace the optical arrangement or the light energy conversion layer translationally relative to the frame element, through one or more translation elements,

wherein the primary optical elements of the first optical layer and the shifting mechanism are designed such that the highly-directional component of incident light is directable onto the light energy conversion elements of the light energy conversion layer and such that the diffuse component of incident light is transmittable through the regions of the light energy conversion layer not covered by the light energy conversion elements, and wherein the amount of light transmitted through the device is controllable.

Thanks to the present invention, it is possible to precisely control the amount of light transmitted to through the device and to efficiently convert light energy of the highly-directional component of the incident light. The converted light is then used for the production of energy by the device while the transmitted light is available for instance for illuminating plants placed below the system and therefore to enable their growth. As illustrated in FIG. 25, thanks to the device according to the present invention, it is possible to increase the amount of light transmitted to the plants during the growth season (doted area) in order to promote their growth during specific periods of the year.

The shifting mechanism of the device can be used to move either the optical arrangement or the light energy conversion layer in order to modulate and control the amount of light energy converted by the light energy conversion elements and the amount of light transmitted through the system. In particular, with the shifting mechanism, it is possible to compensate for the movement of the sun relative to the device during the day and to place the light energy conversion elements always at the most favourable position relative to the primary optical elements of the optical arrangement to maximize the production of energy without the need to use an external tracker as in the CPV modules known from the prior art.

Nevertheless, it is important to understand that the shifting mechanism can be also used to maximize the amount of light transmitted through the device and therefore to maximize the amount of light arriving for instance at plants paced below the system in order to favour their growth. In particular, the shifting mechanism can be used to intentionally misalign the primary optical elements of the optical arrangement relative to the light energy conversion elements, in order to transmit the highly-directional component of the incident light to the plants. This is advantageous when the plants require more irradiance than what diffuse sunlight alone can provide over one day. For instance, the device can provide for a programmable shifting mechanism configured to automatically misalign the primary optical elements relative to the light energy conversion elements in the early mornings or late afternoons, when the sun is low and the efficiency of light energy conversion would anyway be minor. More generally, the device can provide a programmable shifting mechanism configured to misalign the primary optical elements relative to the light energy conversion elements at any time during the day, e.g. based on manual inputs or the feedback of one or more sensors measuring the amount of energy received by the plants and/or the amount of power produced by the light energy conversion elements. This can advantageously be used to match the amount of transmitted light with the optimum light exposure for each kind of goods.

While the light energy conversion elements can be PV cells, they could also be of other types of modules for light energy conversion as for instance thermal modules for the conversion of light energy in heat. The light energy conversion elements of the device of the present invention can also be of different types, for instance a mix of PV cells and thermal cells.

In one preferred embodiment of the present invention, the plurality of primary optical elements and the light energy conversion elements are arranged in regular two-dimensional arrays and the shifting mechanism is arranged to displace the optical arrangement or the light energy conversion layer translationally relative to the frame element in at least two dimensions.

In another preferred embodiment of the present invention, the shifting mechanism is arranged to displace the optical arrangement or the light energy conversion layer in such a way that the highly-directional component of incident light is directable onto the regions of the light energy conversion layer not covered by the light energy conversion elements. As mentioned above, this is particularly advantageous when the plants require more irradiance than what diffuse sunlight alone can provide over one day. For instance, the device can provide for a programmable shifting mechanism configured to automatically misalign the primary optical elements relative to the light energy conversion elements in the early mornings or late afternoons, when the sun is low and the efficiency of light energy conversion would anyway be minor. This can advantageously be used to match the amount of transmitted light with the optimum light exposure for each kind of goods.

In another preferred embodiment of the present invention, the shifting mechanism is arranged to displace the optical arrangement or the light energy conversion layer in such a way that the amount of light transmitted through the device can be maximized and minimized. With this, the device can be used to transmit a maximum of light to the agricultural goods or to almost completely shade them. The latter is particularly advantageous during summer for heat sensitive goods.

In another preferred embodiment of the present invention, the shifting mechanism comprises one or more guiding elements, such as double universal joints, for instance double cardan joints, double ball joints and/or one or more flexible guiding elements, such as a spring or leaf spring, in such a way that the one or more guiding elements or flexible guiding elements are capable of limiting the degrees of freedom of the optical arrangement and/or of the light energy conversion layer. The one or more guiding elements, advantageously flexible guiding elements, capable of limiting the degrees of freedom of the one or more translation elements are arranged in such a way that the relative position of the optical arrangement and the light energy conversion layer can be accurately adjusted by the shifting mechanism, and more specifically avoiding or minimizing relative rotations. In this manner, the shifting mechanism ensures that the relative movement of the optical arrangement and the light energy conversion layer occurs only in translation, without rotation. Flexible guiding elements based on mechanical deformation are advantageous for mechanical systems requiring high reliability and long lifetime, such as the device of the present invention, since they do not involve friction and do not suffer from wear. In addition, their rigidity in the direction perpendicular to the movement and their precision in carrying out small displacements qualify them particularly for this type of systems. Furthermore, avoiding relative rotation between the optical arrangement and the light energy conversion layer is critical to precisely control the light directed to the light energy conversion elements and the light transmitted to the agricultural goods. Indeed, it allows for accurately directing the highly-directional component of incident light either onto the light energy conversion elements or onto the transparent regions of the light energy conversion layer.

In another preferred embodiment of the present invention, the one or more guiding elements and/or the one or more flexible guiding elements are capable of suppressing any rotational movement between the optical arrangement and the light energy conversion layer. This is of particular importance since any spurious rotational movement between the optical arrangement and the light energy conversion layer results in a misalignment between the primary optical elements of the optical arrangement and the light energy conversion layer, which does not allow for a precise control of the amount of light transmitted through the device.

In a further preferred embodiment of the present invention, the light energy conversion layer is directly attached to the optical arrangement by means of the guiding elements and/or the flexible guiding elements. The direct mechanical link provided by these guiding elements ensures a more accurate positioning of the optical arrangement and the light energy conversion layer relative to each other.

In another preferred embodiment of the present invention, the guiding elements and/or the flexible guiding elements are arranged to guide the movement of the optical arrangement or the light energy conversion layer on a paraboloid or on a spherical trajectory. With this, the light energy conversion elements or the transparent regions of the light energy conversion layer can be positioned at the focal point of the primary optical elements independently of the angle of incidence of the highly-directional component of the incident light. Furthermore, a curved displacement trajectory can be advantageous to increase the efficiency and/or the angular acceptance of the device.

In a further preferred embodiment, the device comprises a gutter attached to the frame for collecting rainwater falling on the device. By means of the gutter, it is possible to collect rain falling on the front surface of the device and distribute collected water to the agricultural goods placed below. This is advantageous to avoid depriving plants below the device of water and to avoid or reduce the need for artificial irrigation.

In yet another preferred embodiment of the present invention, the device comprises a water distribution system for distributing the collected rainwater. This allows for distribution of the collected rainwater to the plants placed below or nearby the device.

In another preferred embodiment of the present invention, secondary optical elements of refractive type and/or of reflective type are mounted directly onto the light energy conversion elements in order to further focus the highly-directional component of incident light onto the light energy conversion elements. The secondary optical elements mounted directly on the light energy conversion elements have two main advantages. First, they ensure a better collection of the highly-directional component of the incident light by the light energy conversion elements since the secondary optical elements allow for the collection of a portion of the highly-directional component of incident light that would otherwise miss these light energy conversion elements and be lost. Second, the secondary optical elements allow for increasing the alignment tolerance between the primary optical elements and the light energy conversion elements. In case several light energy conversion elements are mounted on the light energy conversion layer, the light concentrated and transmitted by each primary optical element of the optical arrangement can be slightly misaligned. The secondary optical elements minimize the losses related to this misalignment. It is, however, important to note that even with the secondary optical elements, the diffuse component of incident light is transmitted to the goods placed below the device and the device can be intentionally misaligned in order to transmit the highly-directional component of incident light to the goods. In other words, the secondary optical elements allow for a more precise light exposure regulation and more efficient energy production.

In another preferred embodiment of the present invention, a light scattering layer is placed below the light energy conversion layer in the direction opposite to the optical arrangement. By means of the light scattering layer, it is possible to further homogenize the irradiance which can be very advantageous for the growth of the goods placed below the device.

In yet another preferred embodiment of the present invention, light spectrum shifting elements are integrated into the light energy conversion layer in-between the light energy conversion elements. Thanks to the shifting mechanism, the highly-directional light focused by the optical layer can be directed to these light spectrum shifting elements in order to change the spectrum of the light transmitted by the device. This is advantageous in order to transmit light with a spectrum optimized for the plants being grown below the device (e.g. blue-shifted light below 450 nm or red-shifted light above 650 nm).

In yet another preferred embodiment of the present invention, at least one light emitting element is provided on the light energy conversion layer on the opposite side of the light energy conversion layer from the light energy conversion elements. The light emitting element can provide light to the plants in the absence of sunlight, for instance at night or on cloudy day or provide additional light within a specific spectral band, optimized for the plants being grown. Advantageously, the light emitting element is light emitting diode. It is advantageous to align the light emitting element with a light energy conversion element in order to minimize shading on the transparent light energy conversion layer. In case of a plurality of light emitting elements, it is favorable that each of these elements is aligned with one of the light energy conversion elements.

In a further preferred embodiment of the present invention, the device comprises a plurality of light emitting elements with a plurality of light emission spectra, in particular in the range of wavelengths useful for photosynthesis, typically between 400 and 700 nanometres. Providing a plurality of light emitting elements allows for increasing the light exposure of the goods on cloudy days or at night. Furthermore, the light elements can be of different types, for instance they can have different emission spectra, in order to accommodate for different types of plants placed below the device. Here also, it is advantageous to align the light emitting elements with the light energy conversion elements in order to minimize shading on the transparent light energy conversion layer.

In another preferred embodiment of the present invention, the device is configured to supply the light emitting elements with energy produced by the light energy conversion elements. With this, the device can be energetically self-sufficient which is favourable when several devices are placed on a large agriculture field. Advantageously, the device comprises a battery that is rechargeable by the light energy conversion elements and that can provide energy to the light emitting elements. By this the light emitting elements can provide, for instance at night, plants with light without the need to connect the device to an external energy source.

In a further preferred embodiment of the present invention, quaternary optical elements of refractive type and/or of reflective type are mounted directly onto the light emitting elements in order to direct the emitted light. With the quaternary optical elements, it is possible to direct the light emitted by the light emitting elements and for instance to focus the emitted light onto plants which are placed below the system and are distant to each other. By this, the emitted light can optimally be used, for instance to promote plant growth.

In yet another preferred embodiment of the present invention, the optical arrangement comprises a second optical layer that is bonded to the first optical layer either directly or by means of an adhesive layer. The second optical layer can for instance comprise further optical elements in order to better direct the highly-directional component of the incident light onto the light energy conversion layer.

In a further preferred embodiment of the present invention, the second optical layer is placed on top of the first optical layer in the direction of the source of incident light. In this embodiment, the second optical layer can protect the first optical layer against environmental conditions. Advantageously, the second optical layer has the form of rigid plate, for instance a glass plate, which can be larger than the frame element. This is advantageous to protect the device and the agricultural goods for instance from hail, frost or birds.

In a further preferred embodiment of the present invention, the first optical layer and the second optical layer form a first hermetic space. This is advantageous since the first optical layer is better protected against environmental conditions, in particular against humidity. Moreover, this is advantageous in order to use the optical arrangement as a double-glazed window providing thermal insulation, for instance when the device is used as a façade or roof element of a greenhouse.

In a further preferred embodiment of the present invention, the first optical layer comprises a first optical sub-layer and a second optical sub-layer, wherein the first optical sub-layer and the second optical sub-layer are separated by a third optical layer that is bonded to the first optical sub-layer and to the second optical sub-layer either directly or by means of an adhesive layer. This allows to have a rigid third optical layer, made out of glass for instance, to structure the optical arrangement and a more flexible first optical layer, made out of, for instance, a polymer, such as silicone rubber, moulded or cast to a complex optical shape, for instance by injection moulding. Both first optical layer and third optical layer are then glued or bonded together to form a rigid structure capable of directing the highly-directional component of the incident light onto the light energy conversion elements or onto the transparent region of the light energy conversion layer.

In another preferred embodiment of the present invention, the optical arrangement comprises a fourth optical layer that is bonded to the first optical layer either directly or by means of an adhesive layer, wherein the fourth optical layer is placed on top of the first optical layer in the direction of the light energy conversion layer. With this, the device can be used as a triple-glazed window and allows for further thermal insulation capability of the device, which is advantageous when the device is used as a façade or roof element of a greenhouse.

In yet another preferred embodiment of the present invention, the first optical layer and the fourth optical layer form a second hermetic space. This is advantageous since the optical arrangement is better protected against environmental conditions in particular against humidity. Furthermore, it allows for a better thermal insulation and therefore more efficient triple-glazed windows can be manufactured with the device. This is advantageous when the device is used as a façade or roof element of a greenhouse.

In yet another preferred embodiment of the present invention, the first hermetic space and/or the second hermetic space is filled by an inert gas, as for instance argon, helium, neon, radon, xenon, krypton or a combination thereof. This advantageous when using the device as double-glazed or triple-glazed window of a greenhouse since it improves the thermal insulation capability of the system without diminishing the energy conversion capability.

In a further preferred embodiment of the present invention, the second optical layer, the third optical layer and/or the fourth optical layer is made out of a rigid material, such as glass or acrylic (PMMA). This allows for increasing the rigidity of the optical arrangement and protect the subsequent optical layers from mechanical shocks or environmental pollution, such as dust or humidity. This is particularly favourable when the device is used on an agriculture field or as façade or roof element of a greenhouse. The second optical layer is typically flat, i.e. without optical elements, but it can be also patterned to alter the path or distribution of light. Furthermore, the front optical layer can be coated with a single- or double-sided anti-reflective coating to improve light transmission.

In a further preferred embodiment of the present invention, the first optical layer, the second optical layer, the third optical layer and/or the fourth optical layer is formed by molding, in particular by injection or compression molding, or by glass rolling. Injection molding is a well-known industrial method to produce optical elements with high precision. Glass rolling is typically less accurate but cheaper.

In another preferred embodiment of the present invention, the first optical layer is made of a flexible material, such as silicone rubber. By using a flexible material, it is particularly simple to pattern the first optical layer and to form the primary optical elements.

In a further preferred embodiment of the present invention, the number of primary optical elements is equal to the number of light energy conversion elements. With this, there is a one-to-one relationship between the primary optical elements and the light energy conversion elements. This permits for alternatively converting or transmitting a maximum of the light energy of the highly-directional component of the incident light.

In a further preferred embodiment of the present invention, the number of primary optical elements is larger than the number of light energy conversion elements. This allows for transmitting a portion of the highly-directional component of the incident light through the system. This is advantageous in applications where a larger amount of transmitted light is required.

In a further preferred embodiment of the present invention, the light energy conversion layer comprises a plurality of light shaping elements, wherein the light shaping elements are positioned between the light energy conversion elements and are configured to modify the path of the light impinging on them. By means of the light shaping elements, it is possible to increase the divergence angle of the focused highly-directional component of incident light impinging on a region of the light energy conversion layer not covered by a light energy conversion element. This is advantageous when the device is misaligned in order to control the intensity, direction and/or divergence of the light transmitted through the device.

In another preferred embodiment of the present invention, the light energy conversion layer comprises a plurality of light diffusing elements, wherein the light diffusing elements are positioned between the light energy conversion elements and have transmissivity factors different from the light conversion layer. By means of the light diffusing elements with various degrees of transmissivity that are different from the light energy conversion layer it is possible to control the degree of transmissivity of the beam of direct light focused by the optical layer. Thanks to the shifting mechanism, the focused light can be targeted onto one or none of the light diffusing elements, in order to transmit light with a controlled degree of transmissivity.

In another preferred embodiment of the present invention, the light energy conversion layer comprises a spectral filter, in particular a UV and/or infrared light filter. This is advantageous to avoid heating the crops with radiant energy in wavelengths that are not used for the photosynthesis.

In a further preferred embodiment of the present invention, the device comprises one or more sliders, arranged between the light energy conversion layer and the optical arrangement, and one or more pre-constraining elements. The one or more slider can be fixed on either of its ends and sliding on the other, or it can be arranged to slide on both ends. For instance, the sliders can be fixed to the optical arrangement on one end and sliding on the light energy conversion layer on the other end, or vice-versa. A pre-constraining element, such as a spring, can be arranged on the same axis as the sliders, to ensure that the sliders are always in contact with the surface they are sliding on. With an appropriate number of sliders, the distance between the optical arrangement and the light energy conversion layer can be accurately and reliably preserved over the whole surface of the device. Furthermore, the rigidity of the device on the axis perpendicular to the surface of the optical arrangement is greatly increased, lowering the rigidity requirements on other guiding elements of the shifting mechanism. By the means of sliders, the precision of the alignment between the optical arrangement and the light conversion layer is increased and the amount of light transmitted through the device can be more accurately be controlled.

In a further preferred embodiment of the present invention, the device comprises sliding pads between a slider and a surface they are sliding on. With the sliding pads, it is possible to reduce friction and/or to locally change the slope of the surface on which the sliding occurs. More specifically, the sliding pads can have any desired curvature, for instance a portion of sphere, in such a way that when the slider is moving laterally on the sliding pad, the distance between the optical arrangement and the light energy conversion layer is changing according to the desired curvature. Otherwise said, a lateral displacement induces a controlled vertical displacement. This configuration is advantageous to increase the light transmission and conversion efficiency and/or the angular acceptance of the device.

In a further preferred embodiment of the present invention, the primary optical elements are of reflective type such as mirrors or of refractive type such as lenses including plano-convex, plano-concave, bi-convex, bi-concave, meniscus type and aspheric curvature having polynomial shape.

Optical elements such as lenses with aspheric curvature, advantageously with an aspheric curvature described by a polynomial of order three or higher, and in particular aspheric curvature including one or more inflection points, allow for a higher design freedom to increase the angular acceptance and reduce optical aberrations. This allows for efficiently concentrating the highly-directional component of the incident light onto the light energy conversion elements or onto the transparent regions of the light energy conversion layer. Thanks to the higher concentration factor, high-efficiency PV cells can be used since the area of expensive light energy conversion elements can be reduced, thus decreasing the cost. Furthermore, concentration typically increases the efficiency of the light energy conversion elements. With smaller light energy conversion elements, the surface of the light energy conversion layer able to transmit light is larger, which allows to transmit more diffuse light to agricultural good placed below the system.

In yet another preferred embodiment of the present invention, the primary optical elements have a hexagonal or rectangular tiling contour. This permits to cover completely the surface of the optical arrangement with the primary optical elements without having any gap between these elements.

In another preferred embodiment of the present invention, the light energy conversion elements are PV cells, for instance high-efficiency PV cells. With this, the highly-directional component of the incident light can be directly converted into electricity. Thanks to the focusing power of the optical layer, the surface covered by these cells is smaller than for conventional PV modules and the surface of the light energy conversion layer that is capable of transmitting the diffuse component of the incident light is bigger. Therefore, with high-efficiency PV cells, the highly-directional component of the incident light can be more efficiently converted into electricity while simultaneously transmitting diffuse light through the device. This is particularly advantageous when the device is used in the agricultural field.

The light energy conversion elements can be single- or multi-junction PV cells. Multi-junction PV cells are very efficient but expensive while single-junctions PV cells are less efficient but much cheaper. Furthermore, the light energy conversion elements can advantageously be triple-junction cells based on III-V semiconductors, such as GaInP/GaInAs/Ge or InGaP/GaAs/GaInAsNSb, which can reach efficiencies of more than 40% under concentration. Alternatively, the light energy conversion elements can be dual-junction cells or tandem cells, such as perovskites-silicon tandem cells, which have the potential to offer better performance-to-cost ratios. It should be noted that the junctions of the multi-junction cells can be grown by epitaxial processes or stacked mechanically. In case of single-junction cells, they can advantageously be mono-crystalline silicon cells, poly-crystalline silicon cells, or thin-film solar cells such as Copper Indium Gallium Selenide (CiGS), Cadmium Telluride (CdTe) or amorphous silicon, which are all mass-produced at very low cost. Nonetheless, they can also be made from other technologies/materials such as hetero-junction silicon cells or perovskites.

In yet another preferred embodiment of the present invention, the light energy conversion layer is encapsulated in an encapsulating layer, which is sandwiched between a first protective layer and a second protective layer. The encapsulating layer can for instance be made out of ethylene-vinyl acetate (EVA), or poly-ethylene-vinyl acetate (PEVA). Thanks to the presence of the encapsulating layer and of the first and second protective layer, it is possible to protect the light energy conversion elements from stress and contaminants, such as humidity or dust. The two protective layers can advantageously be made of glass for its rigidity and resistance to shocks. Alternatively, they can be made of a polymer such as PET to make a more lightweight device.

In yet another preferred embodiment of the present invention, the translation element of the shifting mechanism comprises at least one actuator and a control system such that the optical arrangement or the light energy conversion layer can be moved in one or more degrees of freedom in a translational movement. The translational movement may be configured in one, two or three degrees of freedom accordingly. Higher degree of freedom in translation allows for increasing the accuracy and sensitivity of the system, so that the energy conversion and light transmission yields of the system can be maximized. Advantageously, the control system receives electronic commands from a centralized unit.

In a further preferred embodiment of the present invention, the shifting mechanism comprises two or more actuators disposed in parallel to the same translational axis but at opposite ends of the translation element and one or more actuators disposed in a direction perpendicular to the first two. This configuration allows for canceling any parasitic rotation of the translation element around an axis normal to the optical arrangement, in order to ensure that there is no relative rotation between the light energy conversion layer and the optical arrangement.

According to one preferred embodiment of the present invention, the actuator is an electro-mechanical actuator, an electro-static actuator, a piezo-electrical actuator, a stick-slip actuator or a pneumatic actuator.

In another preferred embodiment of the present invention, the device further comprises sensors to monitor environmental parameters such as irradiance, temperature and/or humidity, allowing to optimize the agricultural production. By this means, optimal growth conditions for the agricultural goods can be obtained.

In a further preferred embodiment of the present invention, the device of the invention further comprises a feedback control loop to monitor the position of the translation element and/or the output power of the device and/or the amount of light transmitted through the device, wherein the feedback control loop is for example an optical sensor, a magnetic sensor or a photovoltaic sensor, a power meter, a temperature sensor or a combination of several of these sensors. The one or more sensors can report information on the relative or absolute position of the translation element, the optical arrangement, or the light energy conversion layer, or a combination thereof, or on the output power efficiency of the system such that the light energy conversion yield of device can be optimized. One or more sensors can be provided to measure the amount of light transmitted through the device and arriving at plants placed below the system.

In another preferred embodiment of the present invention, the device further comprises a microcontroller configured to measure the energy production, the amount of transmitted light, the output signal of an embedded sensor and/or the position of the shifting mechanism. This is advantageous to provide the device with a mean to measure its own status and to allow the device to operate autonomously based on a pre-defined algorithm.

In a further preferred embodiment, the microcontroller is provided on a printed circuit board embedded within a sealed box (junction box) located preferably on the side of the light energy conversion layer opposite to the optical arrangement.

In a further preferred embodiment, the device is provided with a wired or wireless communication bus. This is advantageous to allow the device to communicate its status and sensor measurements to a gateway or database. Moreover, when the communication bus is bidirectional, this provides a mean for a central control unit or gateway to send commands to one or a plurality of devices connected to the same bus, in order to control the light transmission and energy production at installation level.

In another preferred embodiment of the present invention, a flexible membrane seals the gap between the translation element and the frame while allowing the translational element to move both laterally and vertically. In this configuration, the gap between the light energy conversion layer and the frame is sealed, which permits to protect the optical arrangement against environmental conditions while ensuring that light can be transmitted through the device.

In a further preferred embodiment of the present invention, the light energy conversion elements are interconnected by connection lines provided on the light energy conversion layer, wherein the connection lines are made out of a transparent conductive material, such as a transparent conductive oxide. This embodiment is advantageous to guarantee that the light absorbed by the connection lines is minimal and to ensure that the maximum of light not captured by the light energy conversion elements is transmitted through the device.

In a further preferred embodiment of the present invention, tertiary optical elements are provided on top of the light energy conversion layer in direction of the optical arrangement, wherein tertiary optical elements are configured such that the amount of light impinging on the connection lines is minimized. The tertiary optical elements allow for instance to modify the path of the light that otherwise would impinge on the connection lines of the light energy conversion elements and thus would be lost. Thanks to the tertiary optical elements, this light is redirected and transmitted through the device.

In another preferred embodiment of the present invention, the device comprises several optical arrangements, and several light energy conversion layers, wherein the shifting mechanism is configured such that it can move all optical arrangements relative to all light energy conversion layers or vice versa.

In yet another preferred embodiment of the present invention, the device is arranged to be attached to a single-axis or dual-axis tracker. This allows for maximizing energy production and/or bringing the device in a preferred position, for instance the vertical position, to increase the space for agricultural machines.

In a second aspect, the present invention relates to a method for light exposure regulation of agricultural goods and energy production by converting or transmitting a highly-directional component of incident light and by transmitting a diffuse component of incident light, with a device according to the present invention, comprising the steps of:
arranging the device between the light source and the agricultural goods, in particular crops;
moving the optical arrangement relative to the light energy conversion layer or vice versa,

wherein the shifting mechanism moves the optical arrangement or the light energy conversion layer translationally by one or more translation element in such a way that the amount of light transmitted through the device to the agricultural goods is adjusted.

Thanks to this method, it is possible to efficiently and precisely regulate the light exposure of agricultural goods placed below the device while converting the light energy not transmitted through the system by means of the light energy conversion elements. The converted light is then used for the production of energy by the device while the transmitted diffuse light is available for illuminating plants placed below the system and therefore to enable their growth. The shifting mechanism of the device can be used to move either the optical arrangement or the light energy conversion layer in order to modulate and control the amount of light energy converted by the light energy conversion elements and the amount of light transmitted through the system. In particular, with the shifting mechanism it is possible to compensate for the movement of the sun relative to the device during the day and to place the light energy conversion layer always at the most favorable position relative to the primary optical elements of the optical arrangement to regulate the light exposure of the system and/or to maximize the energy production.

In one preferred embodiment of this aspect of the present invention, the highly-directional component of incident light is alternatively directed onto the light energy conversion elements of the light energy conversion layer and onto the regions of the light energy conversion layer not covered by the light energy conversion elements and wherein the diffuse component of incident light is transmitted through the regions of the light energy conversion layer not covered by the light energy conversion elements. By this, the highly-directional component of incident light, for instance sunlight, can be transmitted through the system and is available for the agricultural goods placed below the device.

In another preferred embodiment of this aspect of the present invention, the agricultural goods are additionally illuminated by at least one light emitting element provided on the opposite side of the light energy conversion layer from the light energy conversion elements. The light emitting element can provide light to the plants in the absence of sunlight, for instance at night or on cloudy day or provide additional light within a specific spectral band, optimized for the plants being grown. Advantageously, the light emitting element is a light emitting diode. It is advantageous to align the light emitting element with a light energy conversion element in order to minimize shading on the transparent light energy conversion layer.

In a further preferred embodiment of this aspect of the present invention, the agricultural goods are illuminated by a plurality of light emitting elements, wherein the light emitted by the light emitting elements have different spectral components within the range of wavelengths used for photosynthesis, typically between 400 and 700 nanometers.

In yet another preferred embodiment of this aspect of the present invention, the light emitting element is provided with energy by the light energy conversion elements. With this, the method does not need an external source to provide energy to the light emitting element and can therefore be applied on large agriculture field where it is not possible to provide for an external source of energy.

In a further preferred embodiment of this aspect of the present invention, the amount of light transmitted through the device to the agricultural goods is adjusted to match on agricultural goods light requirements over seasons. By this means, the favourable growth conditions are attained over all seasons.

In a further preferred embodiment of this aspect of the present invention, the amount of light transmitted through the device to the agricultural goods is increased at the beginning or at the end of a day. With this, favourable light exposure conditions can be attained for a longer period of time during the day.

In another preferred embodiment of this aspect of the present invention, the amount of light transmitted through the device to the agricultural goods is kept constant over the day.

In yet another preferred embodiment of this aspect of the present invention, a temperature measured at the agricultural goods is maintained constant over the day. The amount of light transmitted through the device influences the temperature measured at or nearby the plants. It is for some plants advantageous if this temperature is maintained constant over day. By regulating the amount of light transmitted through device in response to the measured temperature, the latter can be maintained constant.

In a further preferred embodiment of this aspect of the present invention, the energy production is maximized. This is for instance favorable, when the device comprises a rechargeable battery for the light emitting elements. If the battery is empty, the shifting mechanism can bring the energy conversion layer in a position where the energy production yield is maximum in order to rapidly recharge the battery. It is also advantageous when the plants do not need to be illuminated. In such a case, the method can be used for a maximum energy production.

In a third aspect, the present invention relates to the use of a device according to the present invention for light exposure regulation of agricultural goods, such as plants, and for energy production. Thanks to this use, it is possible to efficiently and precisely regulate the light exposure of agricultural goods placed below the device while converting the light energy not transmitted through the system by means of the light energy conversion elements. The converted light is then used for the production of energy by the device while the transmitted diffuse light is available for illuminating plants placed below the system and therefore to enable their growth. The shifting mechanism of the device can be used to move either the optical arrangement or the light energy conversion layer in order to modulate and control the amount of light energy converted by the light energy conversion elements and the amount of light transmitted through the system. In particular, with the shifting mechanism it is possible to compensate for the movement of the sun relative to the device during the day and to place the light energy conversion layer always at the most favorable position relative to the primary optical elements of the optical arrangement to regulate the light exposure of the system and/or to maximize the energy production.

In one preferred embodiment of this aspect of the present invention, the light energy of the highly-directional component of incident light coming from the sun is captured and converted by light energy conversion elements and the diffuse light component of the incident light is transmitted through the device to agricultural goods, such as plants, placed below the device in the direction opposite to the sun.

In a fourth aspect, the present invention relates to the use of a device according to the present invention as façade or roof component of a greenhouse.

### BRIEF DESCRIPTION OF THE DRAWINGS

The foregoing and other objects, features and advantages of the present invention are apparent from the following detailed description taken in combination with the accompanying drawings in which:

FIG. 1A illustrates a first embodiment of the use of a device according to the present invention for agricultural application;

FIG. 1B illustrates a second embodiment of the use of a device according to the present invention for agricultural application;

FIG. 2A is a schematic cross-sectional view of the device according to a first embodiment of this aspect of the present invention, where highly-directional light is impinging at normal incidence angle onto the optical arrangement;

FIG. 2B is a schematic cross-sectional view of the device according to a first embodiment of this aspect of the present invention, where highly-directional light is impinging at a non-normal incidence angle onto the optical arrangement;

FIG. 3 is a schematic cross-sectional view of the device according to the first embodiment of this aspect of the present invention, where the light energy conversion layer is intentionally misaligned in order to transmit highly-directional light;

FIG. 4 is a schematic top view of the optical arrangement according to a second embodiment of this aspect of the present invention, wherein the primary optical elements have a hexagonal contour;

FIG. 5 is a schematic cross-sectional view of the optical arrangement according to a third embodiment of this aspect of the present invention;

FIG. 6 is a schematic cross-sectional view of the optical arrangement according to a fourth embodiment of this aspect of the present invention;

FIG. 7 is a schematic cross-sectional view of the optical arrangement according to a fifth embodiment of this aspect of the present invention;

FIG. 8 is a schematic cross-sectional view of the optical arrangement according to a sixth embodiment of this aspect of the present invention;

FIG. 9A is a schematic cross-sectional view of the light energy conversion layer according to a seventh embodiment of this aspect of the present invention;

FIG. 9B is a schematic cross-sectional view of the light energy conversion layer according to an eighth embodiment of this aspect of the present invention;

FIG. 9C is a schematic cross-sectional view of the light energy conversion layer according to a ninth embodiment of this aspect of the present invention;

FIG. 9D is a schematic cross-sectional view of the light energy conversion layer according to a tenth embodiment of this aspect of the present invention;

FIG. 9E is a schematic cross-sectional view of the light energy conversion layer illustrating the light path of the focused incident light in case of a partial misalignment of the optical arrangement.

FIG. 10 is a schematic cross-sectional view of the light energy conversion layer according to an eleventh embodiment of this aspect of the present invention;

FIG. 11 is a schematic cross-sectional view of the light energy conversion layer according to a twelfth embodiment of this aspect of the present invention;

FIG. 12 is a schematic cross-sectional view of the light energy conversion layer according to a thirteenth embodiment of this aspect of the present invention;

FIG. 13 is a schematic cross-sectional view of the light energy conversion layer according to a fourteenth embodiment of this aspect of the present invention;

FIG. 14 is a schematic cross-sectional view of the light energy conversion layer according to a fifteenth embodiment of this aspect of the present invention;

FIG. 15 is a schematic cross-sectional view of the light energy conversion layer according to a sixteenth embodiment of this aspect of the present invention;

FIG. 16 is a schematic top view of a device according to an seventeenth embodiment of the present invention;

FIG. 17 is a schematic top view of a device according to a eighteenth embodiment of the present invention;

FIG. 18A is a schematic cross-sectional view of the device according to a nineteenth embodiment of this aspect of the present invention, where the light energy conversion layer is in its standard position;

FIG. 18B is a schematic cross-sectional view of the device according to the nineteenth embodiment of this aspect of the present invention, where the light energy conversion layer is in a shifted position;

FIG. 19 is a schematic cross-sectional view of the optical arrangement and the light energy conversion layer according to a twentieth embodiment of this aspect of the present invention;

FIG. 20 is a schematic cross-sectional view of the device according to a twenty-first embodiment of this aspect of the present invention;

FIG. 21 is a schematic cross-sectional view of the device according to a twenty-second embodiment of this aspect of the present invention;

FIG. 22 is a schematic cross-sectional view of the device according to a twenty-third embodiment of this aspect of the present invention;

FIG. 23 illustrates an embodiment in which the device comprises a feedback loop to control the relative position of the light energy conversion layer relative to the optical arrangement;

FIG. 24 illustrates that several devices according to the present invention can be combined to form a single system; and

FIG. 25 illustrates that thanks to the device according to the present invention the light exposure of plants can be matched to its optimal value.

### DETAILED DESCRIPTION OF THE PREFERRED EMBODIMENTS OF THE INVENTION

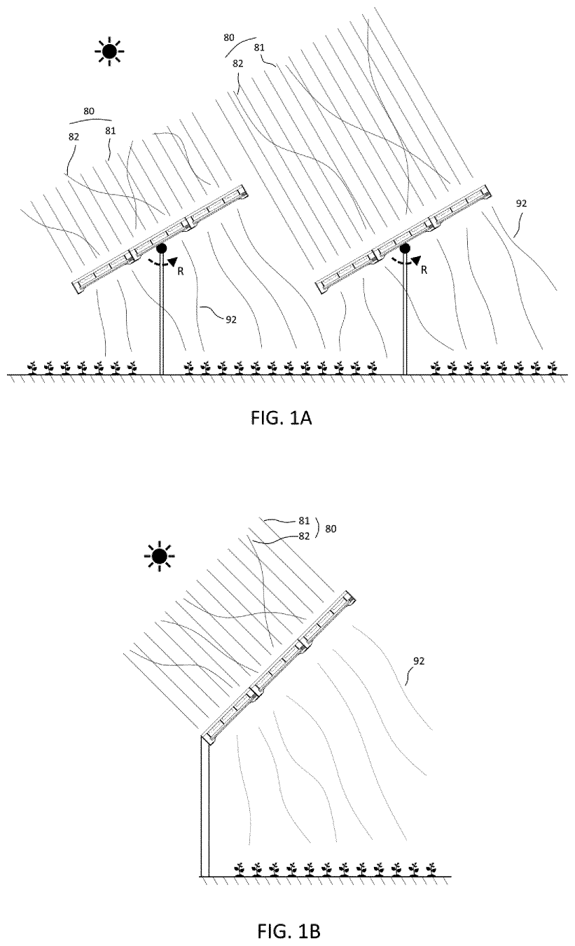

FIGS. 1A and 1B illustrate a first and second embodiment of the use of a device 100 according the present invention for agricultural application. The general principle of the present invention is to provide a device that permits, thanks to shifting mechanism 65 which is able to translate the light conversion layer 50 relative to the optical arrangement 40, either to collect with high efficiency the highly-directional light component 81, i.e. the collimated light, of the entire incident light 80 coming from a light source, as for instance the sun, or to transmit this component of incident light to agricultural goods placed below the device. The device allows also to transmit the diffuse light component 82 of the incident light 80 to the plants. As will be explained in details below the device 100 is configured such that the light energy from the highly directional incident light 81 arriving “directly” from the sun can be converted by PV cells while the diffuse incident light 82 is transmitted through the device, allowing the transmitted diffuse light 92 to arrive at the plants placed below the device. The device further comprises a shifting mechanism (not shown in FIGS. 1A and 1B) that permits to maximise to light energy conversion or the transmission trough the device whatever position of the sun in the sky. As can be seen in these figures, the device can be mounted on a pole either on the side of the system or in the middle. As explained in details below, thanks to the shifting mechanism of the device 100, the tilt angle to the system 100 relative to the ground does not necessarily need to be changed during the day. FIG. 1A illustrates also that the device can be mounted on a single-axis tracker, with rotating axis R, in order to maximize energy production or put the device in a vertical position to increase the space for agricultural machines.

In the field of agriculture, the device allows therefore transmitting direct and diffuse light to plants placed below the device and therefore permits to promote the growth of these plants.

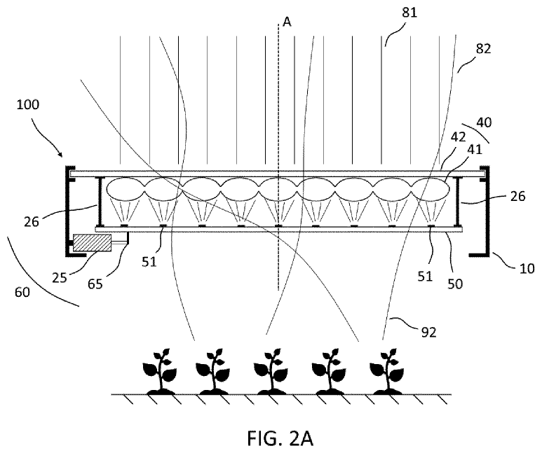

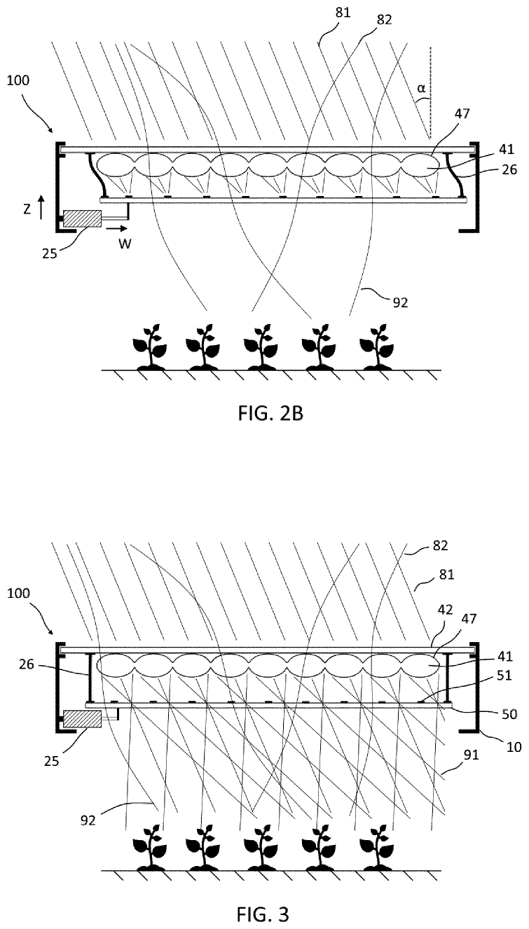

FIGS. 2A and 2B display a photovoltaic device 100 according to first embodiment of the present invention. The device 100 comprises an optical arrangement 40 that comprises at least one first optical layer 41 designed to direct the highly-directional component 81 of the incident light 80 either onto the light energy conversion elements 51 placed on a transparent or translucent light energy conversion layer 50 or onto transparent regions of the light energy conversion layer 50 (the regions between the light energy conversion elements 51), a static frame 10 to which the optical arrangement 40 is attached and a shifting mechanism 60, arranged to move the optical arrangement 40 relatively to the static frame 60, so that the amount of light energy converted by the light energy conversion layer 50 and the amount of transmitted light 92 through this layer can both be adjusted, depending on the relative position of the optical layer 40 and the light energy conversion layer 50. As can be seen in these Figures, the optical layer 40 and the light energy conversion layer 50 are connected together by guiding elements 26, which are in this particular embodiment flexible guiding elements. The guiding elements 26, an actuator 25, and a shifting element 65 are parts of the shifting mechanism 60. The aim of the shifting mechanism 60, and especially of the guiding elements 26, the actuator 25 and of the translation element 65, is to move the light energy conversion layer 50 while allowing only translation along the direction W. In particular, the shifting mechanism 60 is configured such that it forbids any relative rotation, around an axis Z perpendicular to the plane of the device, between the optical arrangement 40 and the light energy conversion layer 50. Important to note is that even if in FIGS. 2A and 2B the light energy conversion layer 50 is movable relative to the frame 10 and the optical arrangement 40 fixed, the device according to the present invention could provide for a movable optical arrangement 40 and a fixed light energy conversion layer 50. Moreover, in the embodiment presented in FIGS. 2A and 2B the optical arrangement 40 comprises besides the first optical layer 41, that is configured to direct the collimated incident light 81, a second optical layer 42. In this embodiment, the second optical layer 42 takes the form of a rigid transparent plate, for instance a glass plate, that is mainly foreseen to protect the first optical layer 41 against environmental conditions.

FIG. 2A depicts the situation when the incidence of direct sunlight is normal to the plane of the device 100. The optical arrangement 40, here the first optical layer 41, can concentrate and transmit the highly-directional component 81 of the incident light 80 to the light energy conversion elements 51, while diffuse incident 82 is transmitted through the light energy conversion layer 50 allowing transmitted light 92 to arrive at the plants placed below the device 100.

In comparison, FIG. 2B illustrates the device 100 when the highly-directional component 81 of the incident light 80 impinges on the system at a larger incidence angle α, corresponding to a situation when the sun has moved in the sky during the day. Thanks to the shifting mechanism 60, when the highly-directional component 81 of the incident light 80 can still optimally be directed onto the light energy conversion elements 51, while diffuse incident light 82 goes through the system to the plants placed below the device 100. Thanks to the guiding elements 26, the light energy conversion layer 50 is not only moved in translation in direction W but also in a direction parallel to the axis Z (see FIG. 2B). By this, the light energy conversion elements 51 can be located at the focal point of the focusing elements of the first optical layer 41 independently of the position of the source of incident light.

FIG. 3 illustrates that the device 100 is configured such that the shifting mechanism 60 can intentionally misalign the device 100, in order to transmit the highly-directional component 81 of the incident light 80 through the system 100, such that both the diffuse 82 and highly-directional 81 components of incident light 80 can be transmitted to the plants below. This is advantageous when the plants require more irradiance than what diffuse sunlight 82 alone can provide over one day. For instance, the device 100 can be configured to be misaligned in the early mornings or late afternoons, when the sun is low and the efficiency of light energy conversion would anyway decrease. More generally, the device 100 can be configured to be misaligned at any time during the day, e.g. based on manual inputs or the feedback of a sensor measuring the amount of energy received by the plants (not shown here). It should be noted that this misalignment can be total or only partial, allowing to precisely adjust the amount of incident light transmitted to the light energy conversion elements and the amount of incident light transmitted through the module at any time. It is also important to note that in this configuration the additional light 91 transmitted by the device is significantly more diffuse than the highly-directional component 81 of incident light 80. More specifically, thanks to the optical power of the optical arrangement 40, the highly-directional component 81 of incident light 80 is significantly diffused before being transmitted to the plants below the device. This is advantageous to provide a more homogeneous light distribution on the crops.

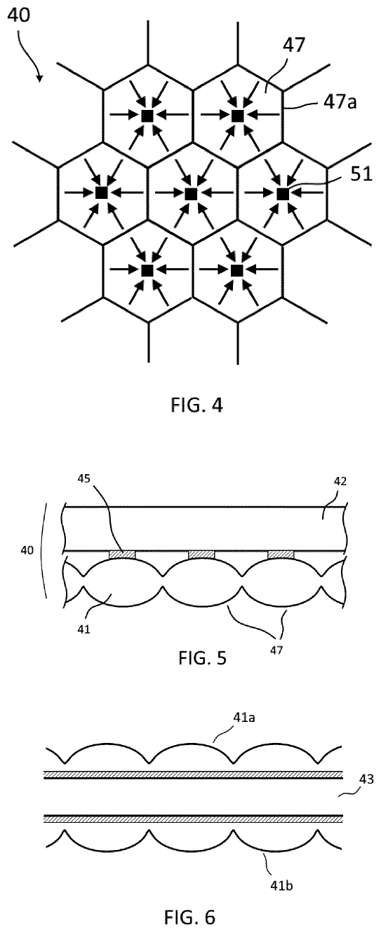

FIGS. 4 to 22 present different embodiments of the optical arrangement 40, the light energy conversion layer 50, and the shifting mechanism 60. Important to note, that these embodiments can be combined to form further embodiments in the frame of the present invention.

As illustrated in FIG. 4, the first optical layer 41 of the optical arrangement 40 of a device according to the present invention can comprise a plurality of primary optical elements 47, for instance lenses or mirrors, that have advantageously a hexagonal contour 47a. By this, the primary optical elements 47 can be arranged side-by-side and cover the entire surface of the first optical layer 41 of the optical arrangement 40 without any gaps.

FIG. 5 illustrates another embodiment of the present invention where the optical arrangement 40 is composed of first and second optical layers 41 and 42 that are attached together. The first and second optical layers 41, 42 can be either directly bonded together, for instance by casting or overmolding processes, or using a plasma activation process (not shown here). The two optical layers 41, 42 can also be bonded together by means of an intermediate adhesive layer 45, as for example silicone glue or UV cured acrylic glue, as depicted in this Figure. The second optical layer 42 is advantageously highly rigid to structure the optical arrangement 40 while a more flexible first optical layer 41, for instance made out of a polymer such as silicone rubber or PMMA, is molded or cast to a complex optical shape, for instance by injection molding.

FIG. 6 shows a further embodiment of the present invention in which the first optical layer 41 of the optical arrangement 40 is composed of a first optical sub-layer 41a and a second optical sub-layer 41b. The first and second optical sub-layers 41 and 41b are advantageously made of a polymer such as silicone rubber, overmolded or bonded on both faces of a third optical layer 43 which is formed as a rigid transparent substrate made for instance out of glass.

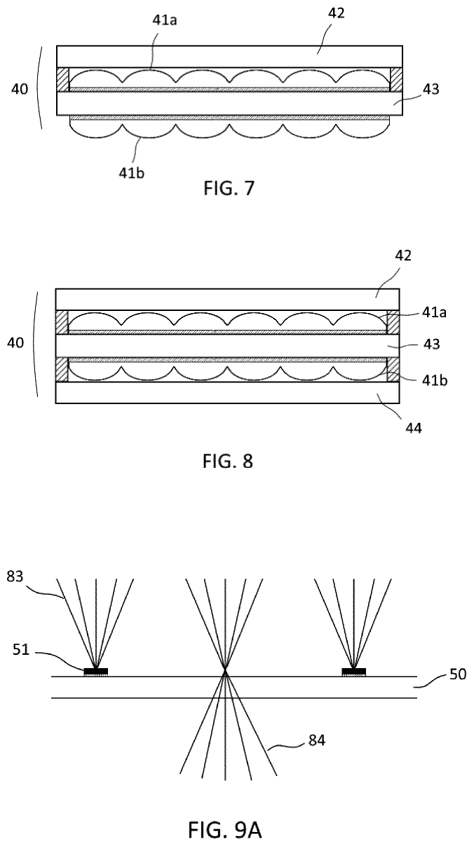

The optical arrangement 40, of the embodiment presented in FIG. 7, comprises a first optical sub-layer 41a, a second optical sub-layer 41b, a second optical layer 42 and a third optical layer 43. Two layers 41a and 41b are made out of a polymer overmolded or bonded on both sides of the rigid third optical layer 43 and attached to another rigid second optical layer 42 on the front side. The space within the two rigid second and third optical layers 42 and 43 can advantageously be hermetically sealed and filled with an inert gas, such as argon, helium, neon, krypton, xenon, radon or a combination thereof. This is beneficial in order to use the optical arrangement 40 as a double-glazed window providing thermal insulation, for instance when the device is used as a façade or roof element of a greenhouse. Similarly, and as shown in FIG. 8, the optical arrangement 40 can be configured as a triple-glazed window. To this aim, a rigid fourth optical layer 44 is added on the backside of the optical arrangement 40 presented in FIG. 7. This is advantageous to add further thermal insulation capability to the device.

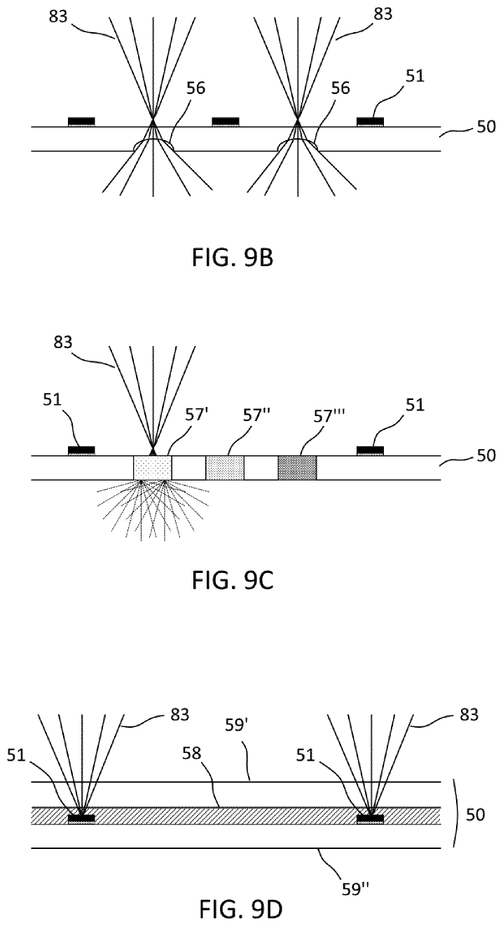

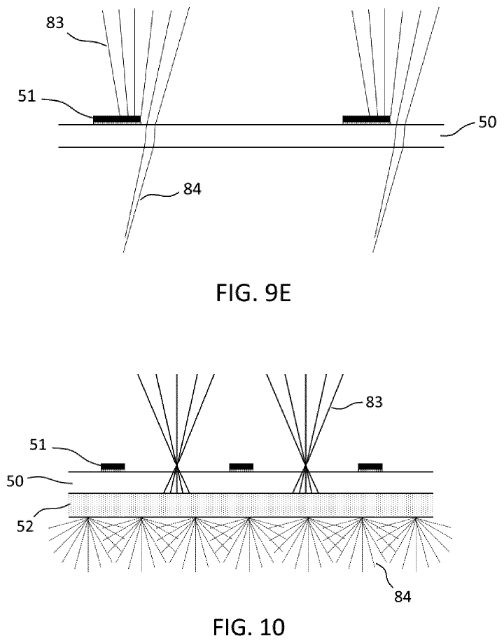

FIG. 9A illustrates a further preferred embodiment of the present invention. In this embodiment, the light energy conversion layer 50 comprises a plurality of light energy conversion elements 51, wherein the number of light energy conversion elements 51 is purposely chosen smaller than the number of primary optical elements 47 in the optical arrangement 40. By this a device with higher light transmission capability can easily be manufactured. As explained below, this is particularly advantageously when the light energy conversion layer 50 of the embodiment presented in FIG. 9A is combined with one of the elements shown in FIGS. 9B, 9C, 9D and 10.

In FIG. 9B, light shaping elements 56 are machined into the light energy conversion layer 50 in order to achieve some desired optical effects, such as increasing the divergence angle of the focused highly-directional component of incident light 83 impinging on a region of the light energy conversion layer not covered by a light energy conversion element 51. This is advantageous when the device is misaligned in order to control the intensity, direction and/or divergence of the light transmitted through the device.

In FIG. 9C, several light diffusing elements 57′, 57″ and 57′″ with various degrees of transmissivity are integrated into the light energy conversion layer 50. This is advantageous in order to control the degree of diffusivity of the beam of direct sunlight focused by the optical layer 40. Thanks to the shifting mechanism 60, the focused light 83 can be targeted onto one or none of the light diffusing elements 57′, 57″ and 57″, in order to transmit light with a controlled degree of transmissivity.

In FIG. 9D the primary light energy conversion elements 51 are encapsulated by encapsulating layer 58, made for instance out of ethylene-vinyl acetate (EVA), or poly-ethylene-vinyl acetate (PEVA). The encapsulating layer 58 is sandwiched between a first protective layer 59′ of the light energy conversion layer and a second protective layer 59″, the two protective layers 59′ and 59″ being transparent or translucent. This is advantageous to protect the light energy conversion elements from stress and contaminants, such as humidity, dust, etc. The two protective layers 59′ and 59″ can advantageously be made of glass for its rigidity and resistance to shocks. Alternatively, they can be made of a polymer such as PET to make a more lightweight device.

FIG. 9E illustrates the light path of the focused highly-directional component of the incident light 83 when the optical arrangement is purposely partially misaligned relatively to the light energy conversion layer 50. Thanks to this misalignment, part of the direct incident light 83 impinges on the light energy conversion elements 51 while another part 84 is transmitted through the layer 50 and can be provided to the agricultural goods placed below the device. With other words, by purposely misaligning the conversion layer 50 towards the optical arrangement 40, the light exposure of the goods placed below the device can precisely be regulated while the component of the incident light not transmitted through the device is used for energy production.

In FIG. 10, a further embodiment of the present invention is depicted. This embodiment is similar to the embodiment shown in FIG. 9 but a light scattering layer 52, for instance in form of a translucent substrate, has been added below the light energy conversion layer 50. This allows to further diffuse focused highly-directional component of incident light 83 in case of misalignment between optical arrangement 40 and light energy conversion layer 50, or when the number of light energy conversion elements 51 is purposely chosen smaller as the number of primary optical elements 47. As can be seen in FIG. 10, the aim of the light scattering layer 52 is to homogenize the illuminance which can be favorable to promote plant growth.

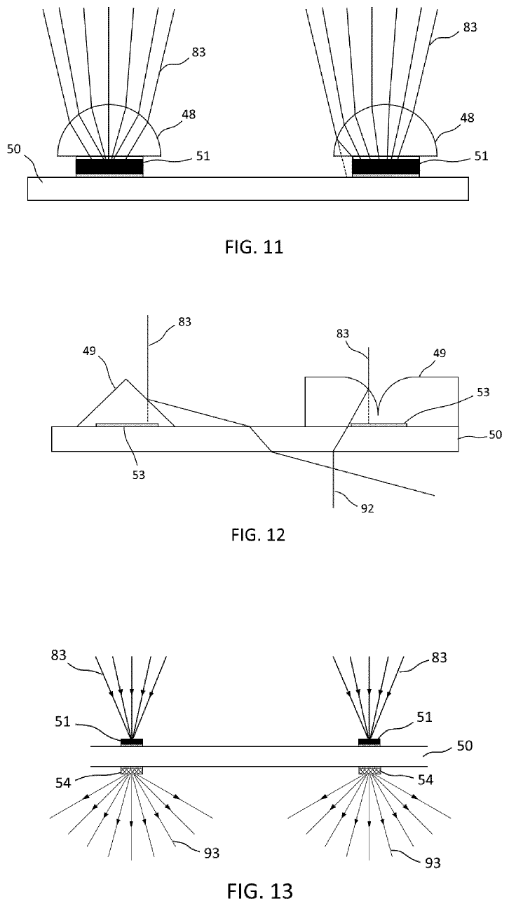

In yet another embodiment of the present invention displayed in FIG. 11, secondary optical elements 48 are provided directly on the light energy conversion elements 51. The secondary optical elements 48 ensure a better collection of focused highly-directional component of incident light 83 by the light energy conversion elements 51. As shown in FIG. 11, the secondary optical elements 48 increase in particular the alignment tolerance between the optical arrangement 40 and the light energy conversion layer 50. When several light energy conversion elements 51 are mounted on the same substrate, the light concentrated and transmitted 83 by each primary optical element 47 of the optical arrangement 40 can be slightly misaligned, as illustrated on the right side of FIG. 11. The secondary optical elements 48 allow therefore for minimizing the losses related to the mentioned possible misalignment. The use of the secondary optical elements 48 allows furthermore to more precisely regulate the light transmitted through the device.

FIG. 12 shows another embodiment of the present invention. Here, tertiary optical elements 49 are arranged on top of opaque structures 53 provided on the light energy conversion layer 50. The tertiary optical elements 49 are configured to modify the path of transmitted light 83 such that it does not impinge on an opaque but not energy producing area of the light energy conversion layer 50 and to ensure optimal transmission through the device. Examples of opaque structures 53 include some connection lines provided to electrically interconnect the light energy conversion elements 51 in form of PV cells, or pads on which the light energy conversion elements 51 or other electrical components are assembled. Tertiary optical elements 49 of reflective or refractive type can be used to “mask” these opaque structures and improve transmission of transmitted light 83 through the light energy conversion layer 50.

As shown in FIGS. 13 to 15 the light energy conversion layer 50 can comprise light emitting elements 54. In the embodiments of these Figures, the device can be used as a lighting fixture, which is advantageous in various scenarios. When the device is installed above agricultural land, the light emitting elements 54 can provide light to the plants in the absence of sunlight, for instance at night or on cloudy days, or provide additional light within a specific spectral band (such as blue-shifted light below 450 nm or red-shifted light above 650 nm), optimized for the plants being grown and their stage of growth.

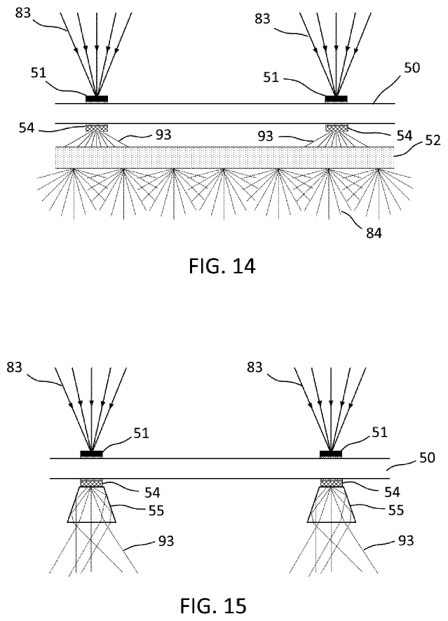

The light emitting elements 54 can be advantageously light emitting diodes, which can be placed on the backside of the light energy conversion layer 50 as shown in FIGS. 13 to 15. It can be advantageous to align the light emitting elements 54 with the light energy conversion elements 51, as shown in FIGS. 13 to 15, in order to minimize shading on the transparent substrate. As illustrated in FIG. 14, an additional light scattering layer 52 can be foreseen to homogenize the output of the light emitting elements 54. Alternatively, as illustrated on FIG. 15, quaternary optical elements 55 can be mounted on the light emitting elements 54 to direct the light output of these elements. Advantageously, the quaternary optical elements 55 are in the form of collimators to collimate the light output of the light emitting elements 54.

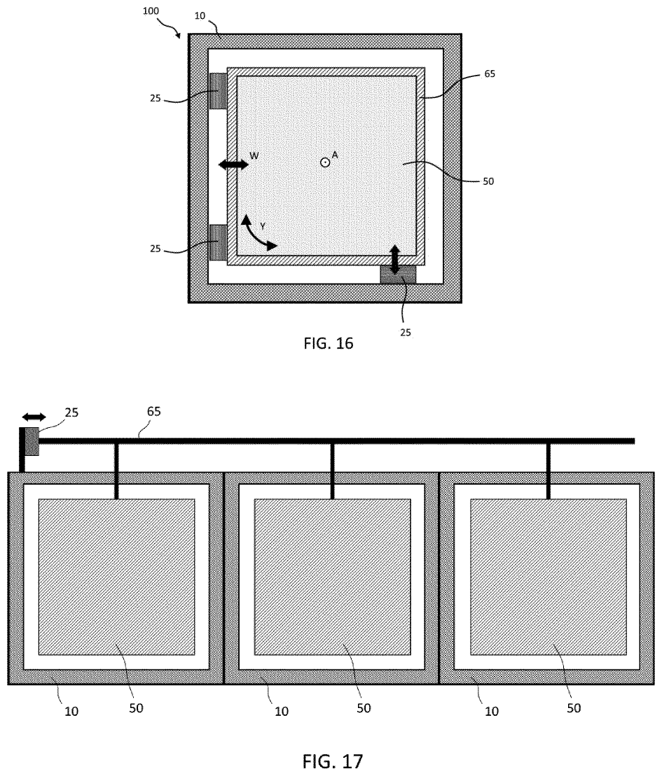

FIG. 16 illustrates that, according to a further embodiment of the present invention, the shifting mechanism 60 comprises three shifting elements 25 here in the form of actuators 25, two of which are disposed in parallel on the same axis W but at opposite ends of the translation element 65, here in the form of a frame around the optical arrangement 40, and a third one in a direction normal to the first two. This configuration permits to control and cancel any parasitic rotation Y of the translation element 65 around the axis A.

It goes without saying that the shifting mechanism 60 as shown in all embodiments of the present invention is capable of moving either the optical arrangement 40 or the light energy conversion layer 50 translationally in one, two or three degrees of freedom relative to the frame element 10, thereby enabling the primary optical elements 47 to optimally direct the highly-directional component 81 of the incident light 80 onto the light energy conversion elements 51.

The different configurations of the present invention allow the translation element 65 of the device to perform only small strokes, ranging from for example from a few micrometers to a few centimeters. Such displacements are typically at least two orders of magnitude smaller than the outer size of the device. The displacements could be for example of the same order of magnitude as the size of the primary optical elements 47. The displacements are limited to translational movements along one, two or three axes (with one, two or three degrees of freedom). Rotations are blocked or cancelled by means of a specific disposition of the guiding elements 26 combined with an arrangement of one or more actuator 25.

As illustrated in FIG. 17, several devices can be combined together, wherein one actuator 25 and one shifting element 65 are configured in such manner that the optical arrangements 40 of all the devices can be translated at the same time.

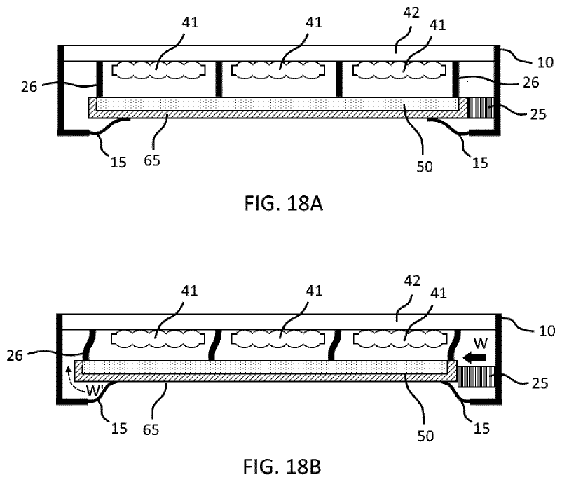

According to another embodiment of the present invention, illustrated in FIGS. 18A and 18B, the light energy conversion layer 50 is directly attached to the optical arrangement 40 by means of several, here four guiding elements 26. In this case, the guiding elements 26 are advantageously flexible guiding elements such as leaf springs, or any suitable type of flexible elements such as double ball joints, double magnetic ball joints or double universal joints, such as double cardan joints. As illustrated in FIG. 18B, the guiding elements 26 are designed in such a way that when the actuator 25 pushes or pulls the translation element 65 in the direction W, the light energy conversion layer 50, mounted on the translation element 65, moves along a curved trajectory W′, for instance a portion of a paraboloid or a spherical trajectory. In other words, the guiding elements 26 transform the linear movement of the actuator 25 into a curved movement of the translation element 65. Of course, and in order to be able to transmit diffuse light to objects, for instance to plants, placed below the optical arrangement, the translation element 65 is transparent or is in a form of a scattering layer 52 as presented for instance in FIG. 10.

In the embodiment of FIGS. 18A and 18B, the frame 10 is at least partially open at the bottom and a flexible membrane 15 is provided between the static frame 10 and the shifting element 65. Of course, the flexible membrane 15 could also be provided between the static frame 10 and the light energy conversion layer 50. The flexible membrane 15 seals the gaps between the translation element 65 or the light energy conversion layer 50 and the frame 10, while allowing the translation element 65 to move both laterally and vertically. Thanks to the flexible membrane 15, the light energy conversion elements 51 (not shown in these figures) and the optical arrangement 40 are protected against environmental conditions in particular against humidity.

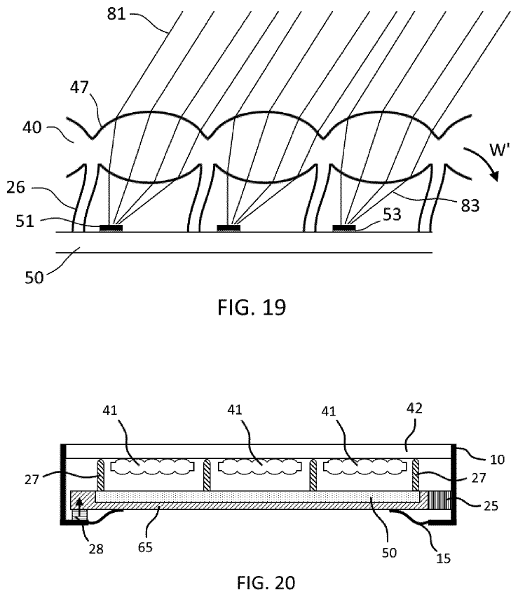

FIG. 19 shows another embodiment of the present invention in which the flexible guiding elements 26 can be foreseen as integral parts of the optical arrangement 40. As illustrated in this Figure, the flexible guiding elements 26 can advantageously be designed such that the optical arrangement 40 is moved along a curved trajectory W′ when the shifting mechanism 60 is actuated. The flexible guiding elements 26 can be attached to the light energy conversion layer 50 by various means, including gluing, clamping or direct molding onto the light energy conversion layer 50.

In another embodiment of the present invention illustrated in FIG. 20, a plurality of sliders 27 are foreseen between the optical arrangement 40 and the light energy conversion layer to ensure, in combination with one or a plurality of pre-constraining elements 28, that the distance between the light energy conversion layer 50 and the optical arrangement 40 is constant over the whole device. The pre-constraining elements 28 can for instance be springs or leaf springs. The number of sliders 27 is typically at least three in the direction of movement of the actuator 25 and increases with the size/surface of the panel. In order to accommodate a plurality of sliders 27, the first optical layer 41 of the optical arrangement 40 can be made of several blocks as illustrated in FIG. 20.

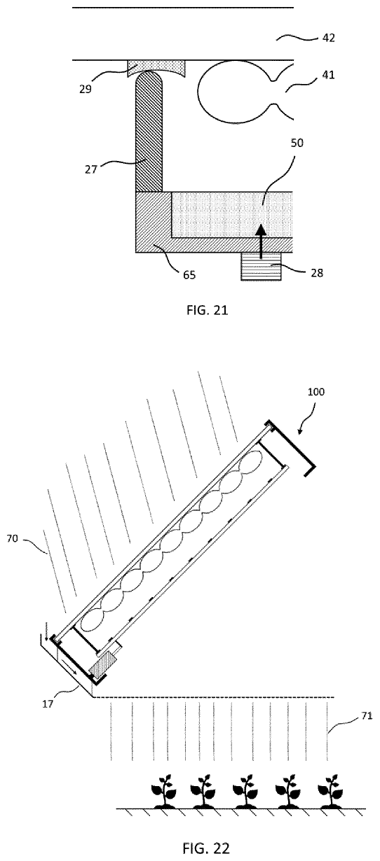

The sliders 27 can slide directly on the surface of one of the layers of the optical system 1, i.e. either the optical arrangement 40 or the light energy conversion layer 50, if necessary with the addition of a coating to reduce friction, or according to a further embodiment of the present invention they can slide on flat or curved sliding pads 29, as shown in FIG. 21. The curvature of the sliding pads 29 can be used to change the distance between the light energy conversion layer 50 and the optical arrangement 40 when the translation element 65 is moved laterally. This is advantageous since with the adaptation of the distance between the optical arrangement 40 and the light energy conversion layer 50, the light energy conversion elements 51 can be brought at the focal point of the primary optical elements 47.

FIG. 22 shows another embodiment of the present invention, where a gutter 17 is attached to the frame of the device 100. The gutter collects rain 70 falling on the front surface of the device and distribute collected water 71 to the plants below. This is advantageous to avoid depriving plants below the device of rainwater and the need for artificial irrigation.

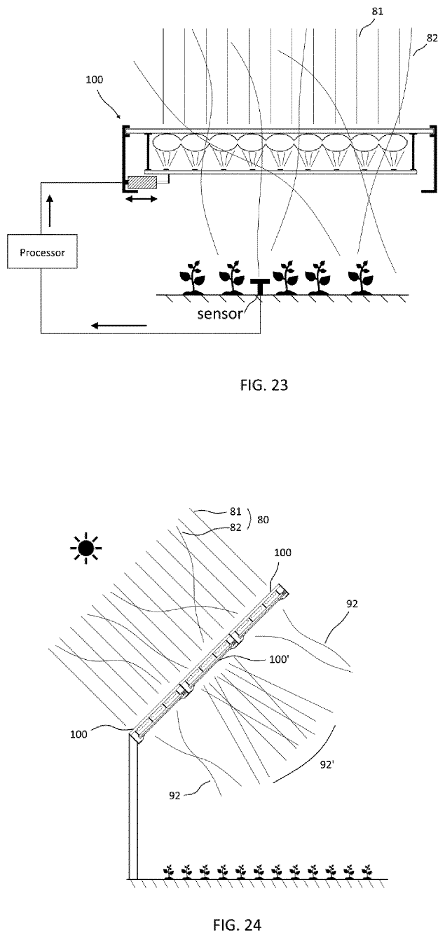

FIG. 23 illustrates that the device 100 can comprise a feedback loop based on a light or a temperature sensor at ground level. The processor can retrieve the measured values from the sensor and shift the light conversion layer accordingly to either increase or decrease the amount of light transmitted through the device 100.

As shown in FIG. 24, multiple devices 100 can be combined in a system. Each of the devices 100 can be configured to transmit more or less light. This is advantageous for instance to have different light intensities on different ground areas/different types of crops, or in order to change the average light transmission over the whole installation.

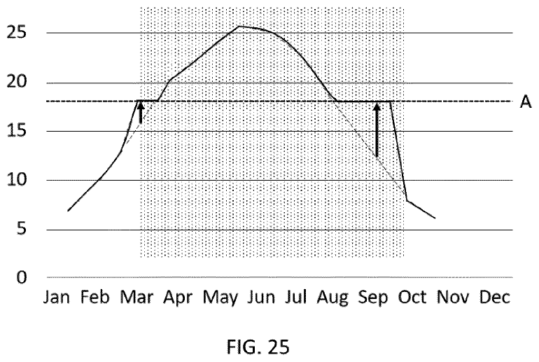

FIG. 25 is an exemplary light transmission plot of a device 100 according to the present invention over a complete year, with the average daily light flux on the vertical axis and months on the horizontal axis. The dashed line A indicates the typical light need of an arbitrary type of crop during its growth season (dotted area). The vertical arrows highlight how the light transmission of the device 100 can be increased to match the light requirements of the crop during specific periods of the year.

Although the present disclosure has been described with reference to particular means, materials and embodiments, one skilled in the art can easily ascertain from the foregoing description the essential characteristics of the present disclosure, while various changes and modifications may be made to adapt the various uses and characteristics as set forth in the following claims.

Reference numbers

| | |
|---|---|
| 10 | frame element |
| 15 | flexible membrane |
| 17 | gutter |
| 25 | actuator |
| 26 | guiding element |
| 27 | sliders |
| 28 | pre-constraining element |
| 29 | sliding elements |
| 40 | optical arrangement |
| 41 | first optical layer |
| 42 | second optical layer |
| 43 | third optical layer |
| 44 | fourth optical layer |
| 45 | adhesive layer |
| 47 | primary optical element |
| 48 | secondary optical element |
| 49 | tertiary optical element |
| 50 | light energy conversion layer |
| 51 | light energy conversion element |
| 52 | light scattering layer |
| 53 | connection lines |
| 54 | light emitting elements |
| 55 | quaternary optical elements |
| 56 | light shaping element |
| 57′, 57″, 57′″ | light diffusing elements |
| 58 | encapsulating layer |
| 59′, 59″ | first and second protective layers |
| 60 | shifting mechanism |
| 65 | translation element |
| 70 | rain |
| 71 | distributed water |
| 80 | incident light |
| 81 | highly-directional component of incident light |
| 82 | diffuse component of incident light |
| 83 | focused highly-directional component of incident light |
| 90 | transmitted light |
| 91 | highly-directional transmitted light |
| 92 | diffuse transmitted light |
| 100 | device |

1. A device for light exposure regulation of agricultural goods and energy production by converting or transmitting a highly-directional component of incident light and by transmitting a diffuse component of incident light, comprising:
an optical arrangement comprising a first optical layer, wherein the first optical layer comprises a plurality of primary optical elements;
a light energy conversion layer at least partially transparent to light and comprising a plurality of distant light energy conversion elements capable of converting light energy in an output energy;
a shifting mechanism for moving the optical arrangement relative to the light energy conversion layer or vice versa; and
a frame element to which either the optical arrangement or the light energy conversion layer is attached,
wherein the shifting mechanism is arranged to displace the optical arrangement or the light energy conversion layer translationally relative to the frame element, through one or more translation element,
wherein the primary optical elements of the first optical layer and the shifting mechanism are adapted such that the highly-directional component of incident light is directable onto the light energy conversion elements of the light energy conversion layer and such that the diffuse component of incident light is transmittable through the regions of the light energy conversion layer not covered by the light energy conversion elements, and wherein an amount of light transmitted through the device is controllable.

2. The device according to claim 1, wherein the plurality of primary optical elements and the light energy conversion elements are arranged in regular two-dimensional arrays, and wherein the shifting mechanism is arranged to displace the optical arrangement or the light energy conversion layer translationally relative to the frame element in at least two dimensions.

3. The device according to claim 1, wherein the shifting mechanism is arranged to displace the optical arrangement or the light energy conversion layer in such a way that the highly-directional component of incident light is directable onto the regions of the light energy conversion layer not covered by the light energy conversion elements.

4. The device according to claim 1, wherein the shifting mechanism is arranged to displace the optical arrangement or the light energy conversion layer in such a way that the amount of light transmitted through the device can be maximized and minimized.

5. The device according to claim 1, wherein the shifting mechanism comprises one or more guiding elements and/or one or more flexible guiding elements in such a way that the one or more guiding elements or flexible guiding elements are capable of limiting degrees of freedom of the optical arrangement and/or of the light energy conversion layer.

6. The device according to claim 5, wherein the one or more guiding elements and/or the one or more flexible guiding elements are capable of suppressing any rotational movement between the optical arrangement and the light energy conversion layer.

7. The device according to claim 5, wherein the light energy conversion layer is directly attached to the optical arrangement by means of the guiding elements and/or the flexible guiding elements.

8. The device according to claim 5, wherein the guiding elements and/or the flexible guiding elements are arranged to guide the movement of the optical arrangement or the light energy conversion layer on a paraboloid or on a spherical trajectory.

9. (canceled)

10. (canceled)

11. (canceled)

12. The device according to claim 1, wherein secondary optical elements are of refractive type and/or of reflective type and are mounted directly onto the light energy conversion elements in order to further focus the highly-directional component of incident light onto the light energy conversion elements.

13. The device according to claim 1, wherein a light scattering layer is placed below the light energy conversion layer in a direction opposite to the optical arrangement.

14. The device according to claim 1, wherein light spectrum shifting elements are integrated into the light energy conversion layer in-between the light energy conversion elements.

15-32. (canceled)

33. The device according to claim 1, wherein the light energy conversion layer comprises a spectral filter, in particular a UV and/or infrared light filter.

34-41. (canceled)

42. The device according to claim 1, further comprising sensors to monitor environmental parameters comprising such as irradiance, temperature and/or humidity, allowing to optimize the agricultural production.

43. The device according to claim 1, further comprising a feedback control loop to monitor a position of the translation element and/or an output power of the device and/or the amount of light transmitted through the device, wherein the feedback control loop comprises an optical sensor, a photovoltaic sensor, a power meter, a temperature sensor or a combination of several of these sensors.

44-47. (canceled)

48. The device according to claim 1, wherein the device is arranged to be attached to a single-axis or dual-axis tracker.

49. The device according to claim 1, wherein the device comprises further comprising a microcontroller configured to measure the energy production, the amount of transmitted light, an output signal of an embedded sensor and/or a position of the shifting mechanism.

50. (canceled)

51. (canceled)

52. A method for light exposure regulation of agricultural goods and energy production by converting or transmitting a highly-directional component of incident light and by transmitting a diffuse component of incident light, with the device according to claim 1, comprising the steps of:
arranging the device between a light source and the agricultural goods; and
moving the optical arrangement relative to the light energy conversion layer or vice versa,
wherein the shifting mechanism moves the optical arrangement or the light energy conversion layer translationally by one or more translation element in such a way that the amount of light transmitted through the device to the agricultural goods is adjusted.

53. A method according to claim 52, wherein the highly-directional component of incident light is alternatively directed onto the light energy conversion elements of the light energy conversion layer and onto the regions of the light energy conversion layer not covered by the light energy conversion elements, and wherein the diffuse component of incident light is transmitted through the regions of the light energy conversion layer not covered by the light energy conversion elements.

54. (canceled)

55. (canceled)

56. A method according to claim 54, wherein the light emitting elements are provided with energy by the light energy conversion elements.

57. A method according to claim 52, wherein the amount of light transmitted through the device to the agricultural goods is adjusted to match on agricultural goods light requirements for the agricultural goods over seasons.

58. A method according to claim 52, wherein the amount of light transmitted through the device to the agricultural goods is increased at the beginning or at the end of a day.

59. A method according to claim 52, wherein the amount of light transmitted through the device to the agricultural goods is kept constant over the day.

60. A method according to claim 52, wherein a temperature measured at the agricultural goods is maintained constant over the day.

61. A method according to claim 52, wherein the energy production is maximized.

62. (canceled)
